(19) United States
(12) Patent Application Publication
(10) Pub. No.: US 2019/0067474 A1
(43) Pub. Date: Feb. 28, 2019

(54) VERTICAL FINFET WITH IMPROVED TOP SOURCE/DRAIN CONTACT

(71) Applicant: GLOBALFOUNDRIES INC., GRAND CAYMAN (KY)

(72) Inventors: Chun Yu WONG, Ballston Lake, NY (US); Hui ZANG, Guilderland, NY (US)

(73) Assignee: GLOBALFOUNDRIES INC., GRAND CAYMAN (KY)

(21) Appl. No.: 15/686,257

(22) Filed: Aug. 25, 2017

(51) Int. Cl. H01L 29/78; H01L 29/66; H01L 29/08; H01L 21/02; H01L 21/265; H01L 29/165; H01L 29/10

(52) U.S. Cl. CPC H01L 29/7827; H01L 29/66666; H01L 29/0847; H01L 21/0245; H01L 21/26506; H01L 21/02667; H01L 21/0274; H01L 29/7848; H01L 29/165; H01L 29/1037; H01L 21/02532; H01L 29/6656; H01L 21/02494

(57) ABSTRACT

A polysilicon layer is deposited over the top surface of the source/drain region of a semiconductor fin in a vertical fin field effect transistor and recrystallized prior to the formation of an epitaxial source/drain region over the source/drain region. The recrystallized silicon material increases the area for deposition of the source/drain region, increasing the available contact area of the source/drain region and correspondingly decreasing the contact resistance thereto. Prior to recrystallization, the polysilicon layer may be made amorphous to improve the quality of the crystalline material for epitaxial growth.

### BACKGROUND

The present application relates generally to semiconductor devices, and more specifically to vertical field effect transistors (VFETs) and their methods of production.

Vertical fin FETs are devices where the source-drain current flows from a source region to a drain region through a channel region of a semiconductor fin in a direction normal to a substrate surface. An advantage of the vertical FET is that the channel length is not defined by lithography, but by methods such as epitaxy or layer deposition, which enable precise dimensional control. In vertical fin field effect transistor (FinFET) devices, the fin defines the transistor channel with the source and drain regions located at opposing (i.e., upper and lower) ends of the fin.

Aggressive scaling of semiconductor devices, including complementary metal oxide semiconductor (CMOS) devices, and the attendant decrease in critical dimension (CD) may result in increased resistance between conductive elements due to a decreased contact area therebetween. It would be beneficial to provide methods and structures for manufacturing advanced node vertical FinFET devices that decrease the contact resistance without altering the principal design rules.

### SUMMARY

In view of the foregoing, in the manufacture of a vertical fin field effect transistor, a polysilicon layer is formed over the top surface of a source/drain region of a semiconductor fin and recrystallized prior to the formation of an epitaxial layer over the source/drain region. The recrystallized silicon provides a template for the epitaxy and effectively increases the area for deposition of the epitaxial layer, which increases the available contact area of the source/drain region during a subsequent step of metallization, and correspondingly decreases the associated contact resistance. That is, the epitaxial layer is formed directly over the recrystallized polysilicon, which presents a larger area for epitaxial growth than the top of the fin. Prior to recrystallization, the polysilicon layer may be made amorphous such as through ion implantation to improve the quality of the crystalline material available for epitaxial growth.

In certain embodiments, the recrystallized polysilicon layer effectively increases a critical dimension (e.g., width) of a top portion of a semiconductor fin, and inhibits unwanted erosion of the fin during various etch processes A semiconductor fin having a width of less than 10 nm, for instance, may have an effective width of 10 nm or more as a result of the over-formed and recrystallized polysilicon layer.

In accordance with embodiments of the present application, a method of forming a structure includes forming a semiconductor fin over a substrate, forming a capping layer over a top surface and over upper sidewall surfaces of the fin such that a width of the capping layer is greater than a width of the fin, and forming an epitaxial layer directly over the capping layer.

A further method of forming a structure includes forming a semiconductor fin over a substrate, forming a polysilicon capping layer over a top surface and upper sidewall surfaces of the fin, amorphizing the polysilicon capping layer to form an amorphous capping layer, recrystallizing the amorphous capping layer to form a single crystal capping layer, and forming an epitaxial layer directly over the single crystal capping layer.

An associated structure includes a semiconductor fin disposed over a substrate, a single crystal capping layer disposed over a top surface of the fin, and an epitaxial layer disposed directly over the capping layer.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 shows the device architecture of a comparative vertical FinFET following the formation of an epitaxial layer over the top surface of a semiconductor fin;

FIG. 2 shows the device architecture of an exemplary vertical FinFET after the formation of an epitaxial layer over a template layer that is disposed over the top surface of a semiconductor fin;

FIG. 3 is a cross-sectional schematic diagram showing a patterned hard mask disposed over a semiconductor substrate;

FIG. 4 shows etching of the substrate using the patterned hard mask as an etch mask to form a plurality of semiconductor fins, and the formation of a bottom spacer layer over a top surface of the etched substrate between adjacent fins;

FIG. 5 depicts the formation of a gate architecture over the fins and the subsequent deposition and planarization of an interlayer dielectric;

FIG. 6 shows a recess etch of the gate architecture followed by the deposition of a low-k dielectric layer within the recessed region and polishing of the low-k dielectric layer;

FIG. 7 depicts a recess etch of the low-k dielectric layer and removal of the patterned hard mask from over the fins and the selective deposition of a polysilicon layer;

FIG. 8 depicts the amorphitization and recrystallization of the polysilicon layer over top surfaces of the fins;

FIG. 9 shows the formation of an epitaxial layer directly on the recrystallized polysilicon layer; and

FIG. 10 shows the formation of a source/drain contact layer over the source/drain regions.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

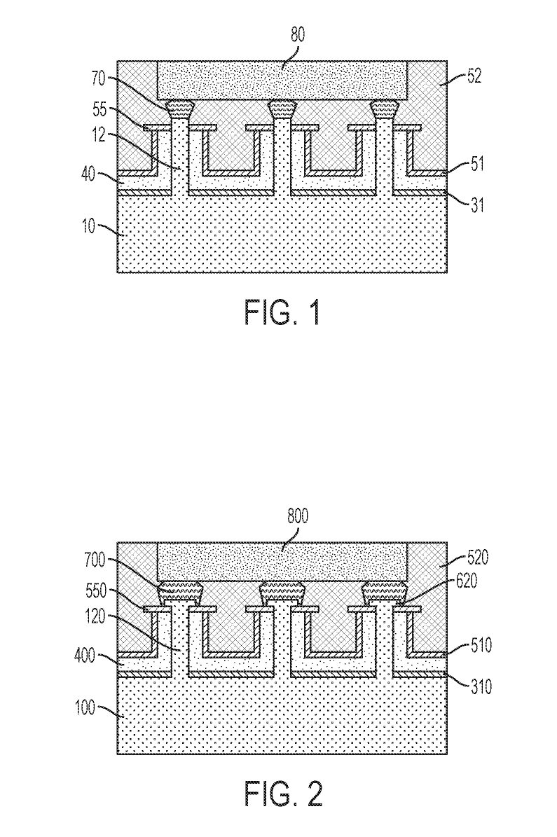

At advanced nodes, in a conventional vertical FinFET, the fin top presents a relatively small cross-sectional area for epitaxial growth of a top source/drain. Referring to FIG. 1, a comparative vertical FinFET structure includes plural semiconductor fins 12 arrayed over a semiconductor substrate 10. A bottom spacer layer 31 and a top spacer layer 55 cooperate with a dielectric liner 51 to separate a gate stack 40 formed proximate to a channel region of each fin from the bottom and top source/drains thereof. An interlayer dielectric layer 52 is disposed over the gate stack 40, and a contact metallization layer 80 is formed within openings in the dielectric layer 52 to electrically contact the top source/drains 70 of the fins 12.

Due to the critical dimension (e.g., width) of the fins 12, the lateral extent of the source/drains 70 formed over each fin 12 is small, which limits the contact area with the metallization layer 80. As used herein “lateral” refers to a direction parallel to a major surface of a substrate. For example, a total lateral width of a top source/drain 70 may be 10 to 50% greater than the width of the underlying fin.

Referring to FIG. 2, depicted is a cross-sectional schematic of the device architecture of an exemplary vertical FinFET following the formation of an epitaxial source/drain region 700 over each of a plurality of semiconductor fins 120 arrayed over a semiconductor substrate 100. The illustrated embodiment shows metallization of a contact opening through an interlayer dielectric (ILD) 520 with a contact metallization layer 800, which is in electrical contact with the top source/drain regions 700 of the fins 120. The interlayer dielectric 520 may be formed by chemical vapor deposition and may comprise, for example, silicon dioxide.

Prior to epitaxial growth of the source/drains 700, a polysilicon layer is deposited over the top of the fins 120 and recrystallized to provide a template layer 620 for epitaxial growth. The template layer 620, which in various embodiments comprises a single crystal material such as single crystal silicon, effectively increases the critical dimension (CD) of the fins 120 proximate to a top surface thereof, and correspondingly increases the lateral dimension(s) of the later-formed source/drain regions 700. In various embodiments, a total lateral dimension of a top source/drain region 700 may be made to be 50 to 500% greater than the width of the underlying fin.

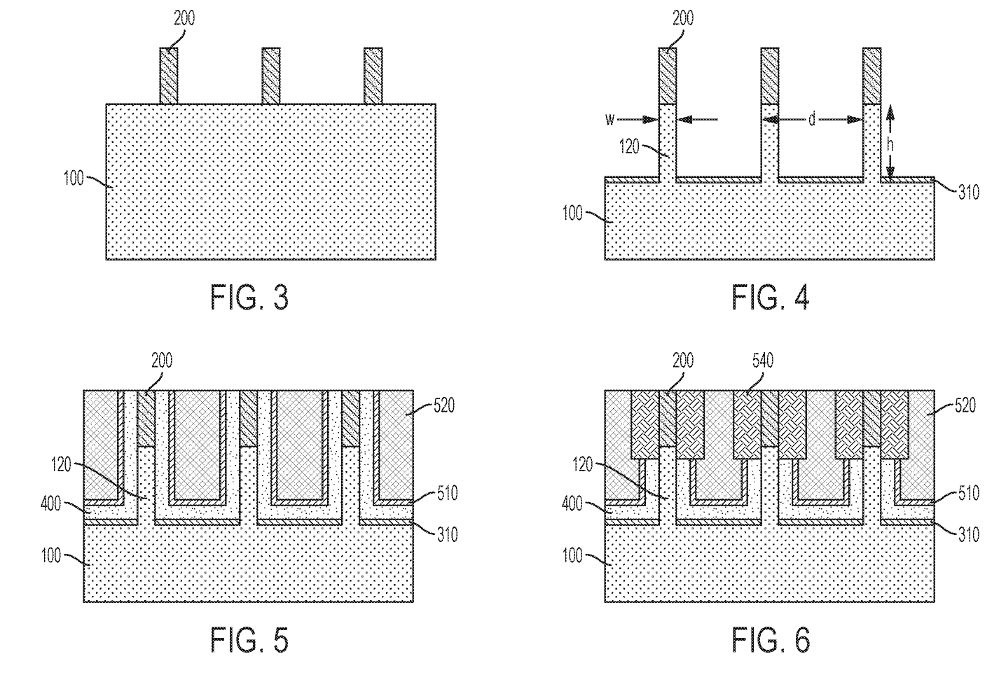

A method of forming the structure of FIG. 2, including the deposition and recrystallization of a template layer over top surfaces of a semiconductor fin to enable epitaxial growth of a wider top source/drain region, is described herein with reference to FIGS. 3-10.

Referring to FIG. 3, shown is a cross-sectional schematic diagram of a semiconductor substrate 100 having a patterned hard mask 200 disposed over a top surface thereof. The substrate 100 may include a semiconductor material such as silicon (Si), e.g., single crystal Si or polycrystalline Si, or a silicon-containing material. Silicon-containing materials include, but are not limited to, single crystal silicon germanium (SiGe), polycrystalline silicon germanium, silicon doped with carbon (Si:C), amorphous Si, as well as combinations and multi-layers thereof. As used herein, the term “single crystal” denotes a crystalline solid, in which the crystal lattice of the entire solid is substantially continuous and substantially unbroken to the edges of the solid with substantially no grain boundaries.

The substrate 100 is not limited to silicon-containing materials, however, as the substrate 100 may comprise other semiconductor materials, including Ge and compound semiconductors, including III-V compound semiconductors such as GaAs, InAs, GaN, GaP, InSb, ZnSe, and ZnS, and II-VI compound semiconductors such as CdSe, CdS, CdTe, ZnSe, ZnS and ZnTe.

Semiconductor substrate 100 may be a bulk substrate or a composite substrate such as a semiconductor-on-insulator (SOI) substrate that comprises, from bottom to top, a handle portion, an isolation layer (e.g., buried oxide layer) and a semiconductor material layer. In the illustrated embodiment, only the topmost semiconductor material layer of such a substrate is shown.

Substrate 100 may have dimensions as typically used in the art and may comprise, for example, a semiconductor wafer. Example wafer diameters include, but are not limited to, 50, 100, 150, 200, 300 and 450 mm. The total substrate thickness may range from 250 microns to 1500 microns, although in particular embodiments the substrate thickness is in the range of 725 to 775 microns, which corresponds to thickness dimensions commonly used in silicon CMOS processing. The semiconductor substrate 100 may comprise (100)-oriented silicon or (111)-oriented silicon, for example.

As will be appreciated by those skilled in the art, and referring to FIG. 4, semiconductor fins 120 may be defined by a patterning process such as photolithography, which includes forming a hard mask 200 over the substrate and forming a layer of photoresist material (not shown) atop the hard mask 200. Hard mask layer 200 may include a material such as, for example, silicon nitride or silicon oxynitride, and may be deposited using conventional deposition processes, such as, for example, CVD or plasma-enhanced CVD (PECVD).

The photoresist material may include a positive-tone photoresist composition, a negative-tone photoresist composition, or a hybrid-tone photoresist composition. A layer of photoresist material may be formed by a deposition process such as, for example, spin-on coating.

The deposited photoresist is then subjected to a pattern of irradiation, and the exposed photoresist material is developed utilizing a conventional resist developer. The pattern provided by the patterned photoresist material is thereafter transferred into the hard mask 200 and then into the substrate 100 utilizing at least one pattern transfer etching process.

In other embodiments, the fin formation process may include a sidewall image transfer (SIT) process or a double patterning (DP) process. The SIT process includes forming a mandrel material layer (not shown) atop the material or material layers (i.e., crystalline silicon) that is to be patterned. The mandrel material layer can include any material (semiconductor, dielectric or conductive) that can be selectively removed from the structure during a subsequently performed etch.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, 5:1, 10:1 or 20:1.

For instance, the mandrel material layer may be composed of amorphous silicon or polysilicon. The mandrel material layer may be composed of a metal such as, for example, Al, W, or Cu. In further examples, the mandrel may comprise a layered structure, such as an organic layer having an oxide layer, e.g., silicon dioxide or SiON formed over the organic layer. The mandrel material layer can be formed, for example, by chemical vapor deposition or plasma enhanced chemical vapor deposition. Following deposition of the mandrel material layer, the mandrel material layer can be patterned by lithography and etching to form a plurality of mandrel structures (also not shown) on the topmost surface of the structure.

The SIT process continues by forming a dielectric spacer on opposing sidewalls of each mandrel structure. The dielectric spacer can be formed by deposition of a dielectric spacer material and etching of the dielectric spacer material. The dielectric spacer material may comprise any dielectric material such as, for example, silicon dioxide, silicon nitride or a dielectric metal oxide. Examples of deposition processes that can be used in providing the dielectric spacer material include, for example, chemical vapor deposition (CVD), plasma enhanced chemical vapor deposition (PECVD), or atomic layer deposition (ALD). Examples of etching that can be used in providing the dielectric spacers include any etching process such as, for example, reactive ion etching.

After formation of the dielectric spacers, the SIT process continues by removing each mandrel structure. Each mandrel structure can be removed by an etching process that is selective for removing the mandrel material. Following the mandrel structure removal, the pattern provided by the dielectric spacers is transferred into the underlying material or material layers, including substrate 100 to form semiconductor fins 120.

The pattern transfer may be achieved by at least one etching process. Examples of etching processes that can used to transfer the pattern may include dry etching (i.e., reactive ion etching, plasma etching, and ion beam etching or laser ablation) and/or a chemical wet etch process. In one example, the etch process used to transfer the pattern may include one or more reactive ion etching steps. In several embodiments, the fins 120 are etched from, and therefore contiguous with the semiconductor substrate 100.

Each of the fins 120 may have a height (h) ranging from 5 nm to 100 nm, e.g., 5, 10, 20, 50, or 100 nm, including ranges between any of the foregoing values, and width (w) of less than 20 nm, e.g., 3, 5, 8, 10, 12 or 15 nm, including ranges between any of the foregoing values. The pitch (d), i.e., repeat distance, between adjacent fins 120 may range from 10 nm to 60 nm, e.g., 10, 20, 30, 40, 50 or 60 nm, including ranges between any of the foregoing values. Although three fin 120 are shown, the present disclosure is not limited to only this example. It is noted that any number of fins 120 may be formed from the semiconductor substrate 100.

After etching the semiconductor substrate 100 to form fins 120, isolation regions (not shown) such as shallow trench isolation (STI) regions may be formed in substrate 100, i.e., between fins, by etching regions of the substrate to form trenches that are back-filled with a dielectric layer. For instance, isolation regions may comprise an oxide such as silicon dioxide. Referring still to FIG. 4, a bottom spacer layer 310 is then formed over the shallow trench isolation and over a top surface of the substrate 100, including directly over a bottom source/drain region of the fins proximate to a top surface of the substrate.

In various embodiments, formation of the bottom spacer layer 310 includes a directional deposition process such as high density plasma (HDP) deposition or gas cluster ion beam (GCIB) deposition to form the spacer material(s) over horizontal surfaces. In further embodiments, formation of the bottom spacer layer 310 includes a non-conformal deposition process such as a chemical vapor deposition (CVD) process of the bottom spacer layer material over the fins, a chemical mechanical polishing (CMP) step to planarize the bottom spacer layer, and a recess etch of the bottom spacer layer to expose a majority of the fin sidewalls and form a bottom spacer layer 310 having a uniform thickness.

As used here, “horizontal” refers to a general direction along a primary surface of a substrate, and “vertical” is a direction generally orthogonal thereto. Furthermore, “vertical” and “horizontal” are generally perpendicular directions relative to one another independent of orientation of the substrate in three-dimensional space.

The thickness of the bottom spacer layer 310 may range from 1 to 10 nm, e.g., 1, 2, 5 or 10 nm, including ranges between any of the foregoing values. The bottom spacer layer 310 may comprise, for example, silicon dioxide (SiO₂). Alternatively, bottom spacer layer 310 may comprise other dielectric materials such as silicon nitride, silicon oxynitride, a low-k material, or any suitable combination of these materials.

Exemplary low-k materials include but are not limited to, amorphous carbon, fluorine-doped oxides, carbon-doped oxides, SiCOH or SiBCN. Commercially-available low-k dielectric products and materials include Dow Corning's SiLK™ and porous SiLK™, Applied Materials' Black Diamond™, Texas Instrument's Coral™ and TSMC's Black Diamond™ and Coral™. As used herein, a low-k material has a dielectric constant less than that of silicon dioxide. Bottom spacer layer 310 is adapted to isolate the bottom source/drain region from a later-formed gate stack.

Referring to FIG. 5, a gate stack 400 is formed above the bottom spacer 310 and over the sidewalls of the fins 120. The gate stack 400 comprises a gate dielectric layer and one or more gate conductor layers, which are deposited in succession. For simplicity, the individual layers of the gate stack 400 are not separately shown.

The gate dielectric may be a conformal layer that is formed over exposed surfaces of the fins 120, i.e., directly over the fin sidewalls, and over the bottom spacer 310. The gate dielectric may comprise silicon dioxide, silicon nitride, silicon oxynitride, a high-k dielectric, and/or other suitable material.

As used herein, a high-k material has a dielectric constant greater than that of silicon dioxide. A high-k dielectric may include a binary or ternary compound such as hafnium oxide (HfO₂). Further exemplary high-k dielectrics include, but are not limited to, ZrO₂, La₂O₃, Al₂O₃, TiO₂, SrTiO₃, BaTiO₃, LaAlO₃, Y₂O₃, HfOₓN_{y}, HfSiOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiOₓN_{y}, SiNₓ, a silicate thereof, and an alloy thereof. Each value of x may independently vary from 0.5 to 3, and each value of y may independently vary from 0 to 2.

The gate dielectric may be deposited by a suitable process such as atomic layer deposition (ALD), chemical vapor deposition (CVD), physical vapor deposition (PVD), thermal oxidation, UV-ozone oxidation, or combinations thereof. The gate dielectric thickness may range from 1 nm to 10 nm, e.g., 1, 2, 4, 6, 8 or 10 nm, including ranges between any of the foregoing values. In various embodiments, the gate dielectric includes a thin layer (e.g., 0.5 nm) of silicon oxide and an overlying layer of high-k dielectric material.

A gate conductor is formed over the gate dielectric. The gate conductor may include a conductive material such as polysilicon, silicon-germanium, a conductive metal such as Al, W, Cu, Ti, Ta, W, Pt, Ag, Au, Ru, Ir, Rh and Re, alloys of conductive metals, e.g., Al—Cu, silicides of one or more conductive metals, e.g., W silicide, and Pt silicide, or other conductive metal compounds such as TiN, TiC, TiSiN, TiTaN, TaN, TaAlN, TaSiN, TaRuN, WSiN, NiSi, CoSi, as well as combinations thereof. The gate conductor may comprise one or more layers of such materials such as, for example, a metal stack including two or more of a barrier layer, work function layer, and conductive fill layer.

The gate conductor may be a conformal layer that is formed over exposed surfaces following deposition of the gate dielectric. The gate conductor can be formed utilizing a conventional deposition process such as, for example, ALD, CVD, metalorganic chemical vapor deposition (MOCVD), molecular beam epitaxy (MBE), PVD, sputtering, plating, evaporation, ion beam deposition, electron beam deposition, laser assisted deposition, or chemical solution deposition. The gate conductor thickness may range from 5 nm to 50 nm, e.g., 5, 10, 15, 20, 30, 40 or 50 nm, including ranges between any of the foregoing values.

Referring still to FIG. 5, a dielectric liner 510 is formed over the gate stack 400. The materials described above with reference to bottom spacer layer 310 may be used to form dielectric liner 510, which may be formed by a conformal deposition process, such as chemical vapor deposition. An interlayer dielectric layer 520 may subsequently be formed on top of dielectric lines 510. Dielectric liner 510 separates the gate stack 400 from interlayer dielectric (ILD) 520. The thickness of the dielectric liner 510 may range from 1 to 10 nm, e.g., 1, 2, 5 or 10 nm, including ranges between any of the foregoing values. The interlayer dielectric (ILD) 520 can be formed over the dielectric liner 510 using a chemical vapor deposition (CVD) process, for example. Interlayer dielectric 520 may comprise silicon dioxide.

As seen with reference still to FIG. 5, the structure after deposition of the gate stack 400, conformal liner 510, and ILD 520, can be planarized, for example, by chemical mechanical polishing (CMP). Chemical mechanical polishing (CMP) is a material removal process that uses both chemical reactions and mechanical forces to remove material and planarize a surface. Patterned hard mask 200 may function as a CMP stop during planarization, which exposes respective top surfaces of the hard mask 200, gate stack 400 and ILD 520. In the illustrated embodiment, top surfaces of the hard mask 200, gate stack 400 and ILD 520 are substantially co-planar.

Following planarization, as shown in FIG. 6, a recess etch of the gate stack 400 and liner 510 is used to reveal the patterned hard mask 200 over the fins. In the illustrated embodiment, the recess etch is to a depth sufficient to expose top sidewall surfaces of the fins 120. A low-k dielectric layer 540 is then backfilled into the recess using, for example, chemical vapor deposition. The overburden from deposition of the low-k dielectric layer 540 is then removed, e.g., using chemical mechanical polishing.

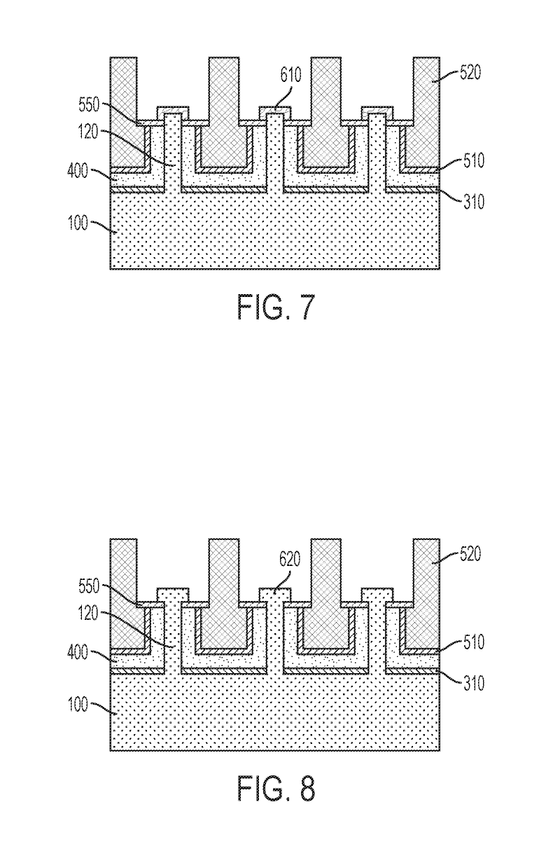

Referring to FIG. 7, shown is the structure of FIG. 6 following a recess etch of the low-k dielectric layer 540 and the removal of the patterned hard mask 200 from over the fins 120. Etching of the low-k dielectric layer 540 and patterned hard mask 200 may be performed simultaneously or successively using one or more etch chemistries selective to ILD 520. Remaining portions of the low-k dielectric layer 540 define a top spacer layer 550 disposed over a top surface of the gate stack 400 and the liner 510. The thickness of the top spacer layer 550 may range from 1 to 10 nm, e.g., 1, 2, 5 or 10 nm, including ranges between any of the foregoing values.

Referring still to FIG. 7, a capping layer 610 of amorphous or polycrystalline silicon is selectively deposited over exposed surfaces of the fins 120. One embodiment of a method for selectively depositing amorphous or polycrystalline silicon includes placing the substrate 100 having exposed silicon regions, i.e., top portions of fins 120, into a chemical vapor deposition (CVD) reactor, and exposing the substrate to a silicon-containing gas. An example silicon-containing gas is silane (SiH₄), although other silicon-containing gases, including other members of the silane family such as disilane (Si₂H₆), may be used. In various embodiments, the capping layer 610 is formed over a top surface and over upper sidewall surfaces of the fins.

A capping layer 610 of amorphous silicon may be formed at a deposition (substrate) temperature in the range 200-550° C., while a capping layer 610 of polycrystalline silicon may be formed at a deposition temperature of 550-750° C. The deposition pressure may range from 100 mTorr to 100 Torr.

The capping layer 610 is deposited directly over exposed portions of the semiconductor fins 120 and, as seen with reference to FIG. 7, extends laterally such that a width of the capping layer 610 is greater than a width of the underlying fin. The capping layer 610 may be deposited over a top surface as well as over upper sidewall surfaces of the fins 120. A thickness of the capping layer 610 may range from 2 to 10 nm, e.g., 2, 4, 6, 8 or 10 nm, including ranges between any of the foregoing values. In various embodiments, a lateral width of the capping layer 610 may be 10 to 200% greater than the width of the underlying fin, e.g., 10, 20, 50, 100, 150 or 200% greater, including ranges between any of the foregoing values.

In embodiments where the as-deposited capping layer 610 is amorphous, an annealing step may be used to crystallize the amorphous phase and form a single crystal capping layer 620. In embodiments where the as-deposited capping layer 610 is polycrystalline, an amorphitization step, such as an amorphizing implant, may be used to prior to an annealing step to promote the formation of a single crystal capping layer 620 during the anneal.

An amorphizing implant may include implanting Si or Ge into the polycrystalline capping layer 610 at a dose greater than 5×10¹³/cm², e.g., between 5×10¹³/cm² and 1×10¹⁵/cm² at an energy of 5 to 10 keV, although lesser and greater doses and lesser and greater implant energies may be used.

An annealing step may be used to crystallize the amorphous capping layer. In various embodiments, the annealing step may comprise a rapid thermal anneal (RTA). Alternatively, a conventional furnace may be used. By way of example, a rapid annealing step may comprise an initial soak step at a temperature between 600 and 800° C. for a time between 10 and 30 seconds, followed by a spike step where the temperature is ramped up to a peak temperature between 1000 and 1100° C., and ramped down from the peak temperature to a temperature below 800° C. The ramp up and ramp down rates may be between 200 and 300° C./min.

The amorphitization step, if used, and recrystallization (annealing) of the as-deposited capping layer 610 to form a single crystal capping layer 620 is depicted in FIG. 8. In various embodiments, recrystallization of the capping layer does not involve a dimensional change, such that the dimensions of the single crystal capping layer 620 are substantially equal to the dimensions of the amorphous or polycrystalline capping layer 610. In various embodiments, a lateral width of the single crystal capping layer 620 may be 10 to 200% greater than the width of the underlying fin, e.g., 10, 20, 50, 100, 150 or 200% greater, including ranges between any of the foregoing values.

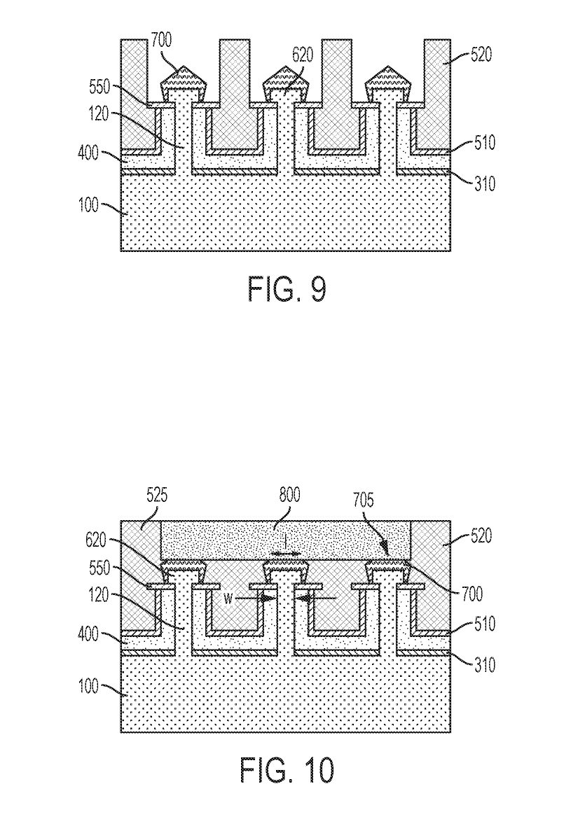

FIG. 9 shows the formation of epitaxial source/drain layers 700 over the fins 120. Top source/drains 700 may be formed by selective epitaxial growth from the single crystal capping layer 620.

The terms “epitaxy,” “epitaxial” and/or “epitaxial growth and/or deposition” refer to the growth of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material has the same crystalline characteristics as the deposition surface on which it is formed. For example, an epitaxial semiconductor material deposited on a (100) crystal surface will take on a (100) orientation. Top source/drain regions 700 may comprise silicon, silicon germanium, or another suitable semiconductor material.

The epitaxial process deposits an epitaxial layer directly onto the exposed surfaces of the single crystal capping layer 620. Exposed surfaces of the single crystal capping layer 620 may include the top surface as well as upper portions of the capping layer sidewalls proximate to the top surface. In various embodiments, an epitaxial source/drain region is formed without deposition onto the exposed dielectric surfaces.

Example epitaxial growth processes include low energy plasma deposition, liquid phase epitaxy, molecular beam epitaxy, and atmospheric pressure chemical vapor deposition. An example silicon epitaxial process for forming top source (or drain) region uses a gas mixture including H₂ and silane (SiH₄) or dichlorosilane (SiH₂Cl₂) at a deposition (e.g., substrate) temperature of 450-800° C. and a growth pressure (i.e., chamber pressure) of 0.1-700 Torr.

The foregoing process may be modified to form a silicon germanium (SiGeₓ) epitaxial source/drain region 700. During such a process, a germanium source such as germane gas (GeH₄) flows concurrently into a process chamber with a silicon source and a carrier gas (e.g., H₂ and/or N₂). By way of example, the flow rate of the silicon source may be in the range of 5 sccm to 500 sccm, the flow rate of the germanium source may be in the range of 0.1 sccm to 10 sccm, and the flow rate of the carrier gas may be in the range of 1,000 sccm to 60,000 sccm, although lesser and greater flow rates may be used. By way of example, the germanium content of a silicon germanium (SiGeₓ) source/drain region 700 may be in the range of 25 to 50 atomic percent.

As will be appreciated, other suitable gas sources for silicon include silicon tetrachloride (SiCl₄), trichlorosilane (SiHCl₃), and other hydrogen-reduced chlorosilanes (SiHₓCl₄₋ₓ). In lieu of germane, other germanium sources or precursors may be used to form epitaxial silicon germanium layers. Higher germanes include the compounds with the empirical formula GeₓH₍₂ₓ₊₂₎, such as digermane (Ge₂H₆), trigermane (Ge₃H₈) and tetragermane (Ge₄H₁₀), as well as others. Organogermanes include compounds with the empirical formula R_{y}GeₓH_{(2x+2-y)}, where R=methyl, ethyl, propyl or butyl, such as methylgermane ((CH₃)GeH₃), dimethylgermane ((CH₃)₂GeH₂), ethylgermane ((CH₃CH₂)GeH₃), methyldigermane ((CH₃)Ge₂H₅), dimethyldigermane ((CH₃)₂Ge₂H₄) and hexamethyldigermane ((CH₃)₆Ge₂).

As seen with reference to FIG. 9, the epitaxial growth naturally forms into faceted, or diamond-shaped structures. The faceted shape results from the different relative growth rates over different crystallographic orientations. For example, the growth rate on silicon (Si) surfaces having (111) orientations is slower than that on other planes such as (110) or (100) planes. Accordingly, the resultant structures result from the slowest epitaxial growth rate on the (111) surface.

In the illustrated embodiment, the vertical surfaces of the fins 120 and overgrown template layer 620 have a (110) crystallographic orientation, while the horizontal top surfaces have a (100) orientation. The faceted top surfaces of the source/drain regions 700 have a (111) orientation. The angle between the (111) surface and (110) surface is 35.3°, and the angle between (111) surface and the (100) surface 54.7°. Compared to a rectangular shape, the diamond-shaped source/drain regions 700 have the advantage of a greater surface area and volume for making electrical contact thereto, and the flexibility of a forming a multi-compositional structure with the underlying fins (e.g., SiGe source/drain regions on silicon fins).

In various embodiments, a total lateral width of a top source/drain region 700 may be 50 to 500% greater than the width of the underlying fin, e.g., 50, 100, 150, 200, 300, 400 or 500%, including ranges between any of the foregoing values. As will be appreciated with reference to FIG. 9, the epitaxial top source/drain region 700 is formed directly over a top surface of the single crystal capping layer 620, and may be formed also directly over sidewall surfaces of the single crystal capping layer 620.

Referring to FIG. 10, additional interlayer dielectric 525 may be formed over top source/drain regions 700 and patterned using conventional photolithography, polishing, and etching techniques to form a contact opening that exposes a top surface of a source/drain region 700. The illustrated embodiment shows metallization of the contact opening through interlayer dielectric (ILD) 520 with a contact metallization layer 800.

Prior to metallization, a CMP step may be used to remove a top portion of the faceted source/drain regions 700 to provide a substantially planar top surface 705. Top surface 705 may have at least one lateral dimension (l) that greater than the width (w) of the underlying fin 120.

According to various embodiments, a lateral dimension (l) of a source/drain region 700 at a planar top surface thereof may be 10 to 200% greater than the width (w) of the underlying fin, e.g., 10, 20, 50, 100, 150 or 200% greater, including ranges between any of the foregoing values.

Illustrated in FIGS. 3-10 are embodiments of a process to form a vertical field effect transistor, as well as the resulting structure, having an improved top source/drain contact. The vertical transistor architecture includes a recrystallized, single crystal layer that is formed over a top source/drain end of a semiconductor fin. The single crystal layer is adapted to template the epitaxial growth of a top source/drain region over the fin.

As used herein, the singular forms “a,” “an” and “the” include plural referents unless the context clearly dictates otherwise. Thus, for example, reference to a “fin” includes examples having two or more such “fins” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a fin that comprises silicon include embodiments where a fin consists essentially of silicon and embodiments where a fin consists of silicon.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A method of forming a structure, comprising:
forming a semiconductor fin over a substrate;
forming a capping layer over a top surface and over upper sidewall surfaces of the fin, wherein a width of the capping layer is greater than a width of the fin; and
forming an epitaxial source/drain region directly over the capping layer.

2. The method of claim 1, wherein a width of the epitaxial source/drain region is 50 to 500% greater than the width of the fin.

3. The method of claim 1, wherein forming the capping layer comprises forming a polysilicon layer over the fin.

4. The method of claim 3, further comprising amorphizing the polysilicon layer to form an amorphous layer.

5. The method of claim 4, wherein the amorphizing comprises ion implantation.

6. The method of claim 4, further comprising recrystallizing the amorphous layer to form a single crystal capping layer.

7. The method of claim 1, wherein the capping layer is a single crystal layer.

8. The method of claim 1, wherein the epitaxial source/drain region comprises silicon germanium.

9. The method of claim 1, wherein the epitaxial source/drain region is formed over a top surface and over sidewall surfaces of the capping layer.

10. A structure, comprising:
a semiconductor fin disposed over a substrate;
a capping layer disposed over a top surface of the fin, wherein the capping layer comprises a single crystal material; and
an epitaxial source/drain region disposed directly over the capping layer.

11. The structure of claim 10, wherein a width of the capping layer is greater than a width of the fin.

12. The structure of claim 10, wherein a width of the epitaxial source/drain region is 50 to 500% greater than a width of the fin.

13. The structure of claim 10, wherein the fin and the capping layer each comprise silicon.

14. The structure of claim 10, wherein the epitaxial source/drain region comprises silicon germanium.

15. The structure of claim 10, wherein the epitaxial source/drain region is formed over a top surface and over sidewall surfaces of the capping layer.

16. A method of forming a structure, comprising:
forming a semiconductor fin over a substrate;
forming a polysilicon capping layer over a top surface and over upper sidewall surfaces of the fin;
amorphizing the polysilicon capping layer to form an amorphous capping layer;
recrystallizing the amorphous capping layer to form a single crystal capping layer; and
forming an epitaxial source/drain region directly over the single crystal capping layer.

17. The method of claim 16, wherein a width of the polysilicon capping layer is greater than a width of the fin.
